(19) United States
(12) Patent Application Publication
(10) Pub. No.: US 2024/0429534 A1
(43) Pub. Date: Dec. 26, 2024

(54) BATTERY MODULE ASSEMBLY

(71) Applicants: HYUNDAI MOTOR COMPANY, Seoul (KR); KIA CORPORATION, Seoul (KR); SEBANG LITHIUM BATTERY CO.,LTD., Anyang-si (KR)

(72) Inventors: Kang Woo Bae, Suwon-si (KR); Hee Gun Yang, Seongnam-si (KR); Sung In Baek, Hwaseong-si (KR); In Hwan Bae, Anyang-si (KR); Young Jin Kim, Anyang-si (KR); Sin Wook Kim, Anyang-si (KR); Dae Han Jang, Anyang-si (KR)

(73) Assignees: HYUNDAI MOTOR COMPANY, Seoul (KR); KIA CORPORATION, Seoul (KR); SEBANG LITHIUM BATTERY CO.,LTD., Anyang-si (KR)

(21) Appl. No.: 18/543,494

(22) Filed: Dec. 18, 2023

(30) Foreign Application Priority Data
Jun. 20, 2023 (KR) 10-2023-0079234

(51) Int. Cl. H01M 50/264; H01M 10/42; H01M 50/213; H01M 50/271; H01M 50/284; H05K 7/20

(52) U.S. Cl. CPC H01M 50/264; H01M 10/425; H01M 50/213; H01M 50/271; H01M 50/284; H05K 7/20409; H01M 2010/4271

(57) ABSTRACT

A battery module assembly includes: a battery pack having a plurality of battery cells; a lower case having an inner space accommodating at least a portion of the battery pack; an upper case having an inner space accommodating the remaining portion of the battery pack that is not accommodated in the lower case, and coupled to the lower case; and at least one lower support portion formed to protrude from an inner surface of the lower case and assist in fixing the battery pack to the lower case.

### CROSS-REFERENCE TO RELATED APPLICATION

The present application claims priority to and the benefit of Korean Patent Application No. 10-2023-0079234, filed on Jun. 20, 2023, the entire disclosure of which is incorporated herein by reference.

### TECHNICAL FIELD

The present disclosure relates to a battery module assembly.

### BACKGROUND

The content described in the present section merely provides background information on the present disclosure and does not constitute the prior art.

Batteries can be divided into a primary battery and a secondary battery. Unlike the primary battery, the secondary battery is a battery that can be charged and discharged. The secondary battery can be used in an electric vehicle (EV), a mobile device, an electric bike, an energy storage system (ESS), and the like. The secondary battery may be used in the form of a single battery or in the form of a pack in which a plurality of battery cells are connected and bundled into one unit, depending on the type of external device in which the secondary battery is used.

The shape of the battery cell may be a cylindrical type, a pouch type, or a prismatic type. A plurality of cylindrical battery cells may be used in the form of a pack in an electric vehicle. At least one cylindrical battery pack may be configured as one module.

A module of cylindrical battery cells may include an anchoring device mounted in a case. The anchoring device may fix a battery pack inside the battery module. The anchoring device maintains the alignment of the battery cells inside the battery module against external physical impact. However, the presence of the anchoring device gives rise to issues within the battery module, namely an increase in both volume and weight.

The battery module may supply or receive power to a battery management system (BMS) using a printed circuit board (PCB). Conventionally, the battery module is configured by contacting the battery pack and the PCB. In other words, the battery pack and the PCB are connected by direct contact. Such a battery module has a problem in that an electrical short circuit may occur between the PCB or BMS and the battery module due to heat generation of the battery cell when charging and discharging the battery cell.

### SUMMARY

In view of the above, the present disclosure provides a battery module assembly which is capable of incorporating a plurality of battery cells in a battery module in a stable structure. This is achieved with a simple assembly process that eliminates the need for any additional anchoring device. As a result, the battery module assembly reduces manufacturing costs, and the risk of an electrical short circuit between a PCB or BMS and the battery module.

In accordance with one embodiment of the present disclosure, there is provided a battery module assembly including a battery pack having a plurality of battery cells, and a lower case having an inner space accommodating at least a portion of the battery pack. The battery module assembly also includes an upper case having an inner space accommodating the remaining portion of the battery pack that is not accommodated in the lower case. The upper case is also coupled to the lower case. The battery module assembly also includes at least one lower support portion formed to protrude at least from an inner surface of the lower case and assist in fixing the battery pack to the lower case.

In one embodiment of the present disclosure, there is provided a battery module assembly including a battery pack having a plurality of battery cells, and a printed circuit board (PCB) electrically connected to the battery pack. The battery module assembly also includes a lower case having a first inner space accommodating at least a portion of the battery pack and a second inner space accommodating at least a portion of the PCB. The battery module assembly also includes an upper case coupled to the lower case so that the first inner space and the second inner space become closed spaces. The first inner space and the second inner space are separately formed so that the battery pack and the PCB do not come into direct contact.

The battery module assembly, according to the embodiments of the present disclosure, allows for the configuration of a stable structure for the battery module, which includes a plurality of battery cells. This is achieved with a simple assembly process without any additional anchoring device. As a result, the battery module assembly reduces manufacturing costs, and reduces the risk of electrical short circuit between a PCB or BMS and the battery module.

### BRIEF DESCRIPTION OF THE DRAWINGS

Since these drawings are for reference in explaining embodiments of the present disclosure, the technical idea of the present disclosure should not be construed as limited to the accompanying drawings.

FIG. 1 is a perspective view of a battery module assembly according to one embodiment of the present disclosure.

FIG. 2 is an exploded perspective view of the battery module assembly according to one embodiment of the present disclosure.

FIG. 3 is an exploded perspective view of a battery pack according to one embodiment of the present disclosure.

FIG. 4 is a cross-sectional view of the battery module assembly according to one embodiment of the present disclosure taken in an electrode arrangement direction of a battery cell.

FIG. 5 is a cross-sectional view of the battery module assembly according to one embodiment of the present disclosure in a direction perpendicular to the electrode arrangement direction of the battery cell.

### DETAILED DESCRIPTION

Hereinafter, embodiments of the present disclosure are described in detail with reference to the accompanying drawings. In the following description, like reference numerals designate like elements, although the elements are shown in different drawings. Further, in the following description of embodiments, a detailed description of known functions and configurations incorporated therein are omitted for the purpose of clarity and for brevity.

Additionally, various terms such as first, second, A, B, (a), (b), and the like, are used solely to differentiate one component from the other but not to imply or suggest the substances, order, or sequence of the components. Throughout the present specification, when a part ‘includes’ or ‘comprises’ a component, the part is meant to further include other components, not to exclude thereof unless specifically stated to the contrary.

When a component is referred to as being “connected” to or “in contact” with another component, it should be understood that it may be directly connected to or in contact with the other component, but other components may exist therebetween. On the other hand, when a component is referred to as being “directly connected” to or “directly in contact” with another component, it should be understood that there is no other component therebetween.

When a component, device, element, or the like of the present disclosure is described as having a purpose or performing an operation, function, or the like, the component, device, or element should be considered herein as being “configured to” meet that purpose or to perform that operation or function.

A battery module according to the present disclosure can be used in a device requiring power supply while repeating charging and discharging periodically or non-periodically. For example, the battery module according to the present disclosure can be used for automobiles, hybrid vehicles, or electric vehicles.

The battery module may include therein a plurality of battery cells. A single battery cell has a limited capacity. In order to increase the capacity of the battery module, the battery module may require that a plurality of battery cells be arranged in a small volume. Further, the battery module may require less weight compared to a conventional battery module.

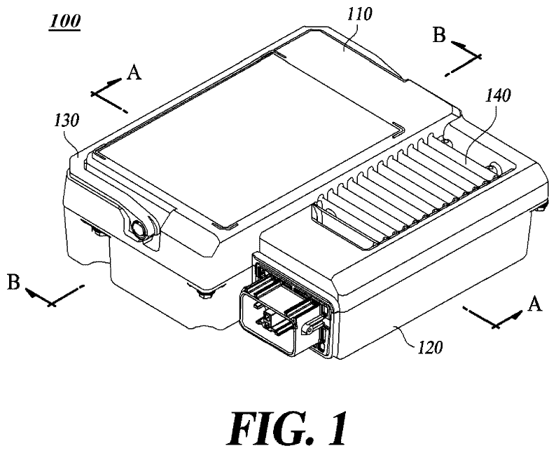

FIG. 1 is a perspective view of a battery module assembly according to one embodiment of the present disclosure.

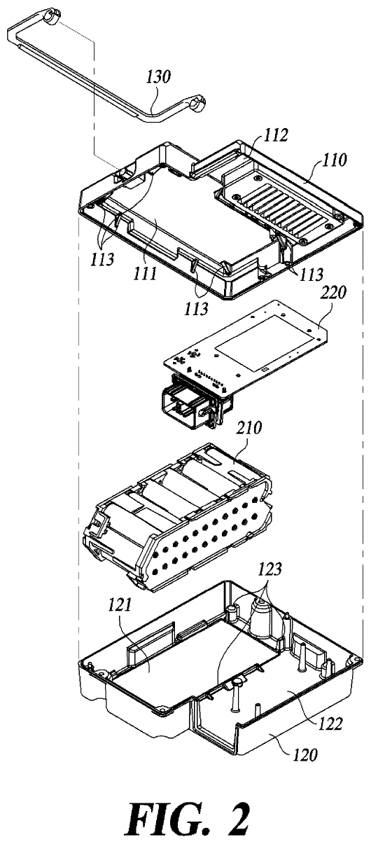

FIG. 2 is an exploded perspective view of the battery module assembly according to one embodiment of the present disclosure.

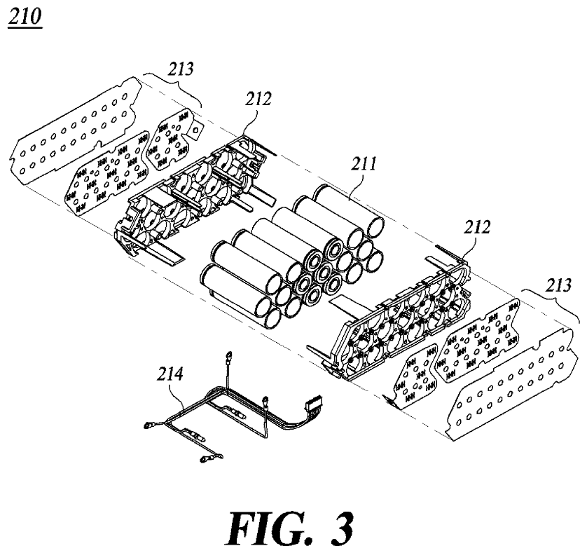

FIG. 3 is an exploded perspective view of a battery pack according to one embodiment of the present disclosure.

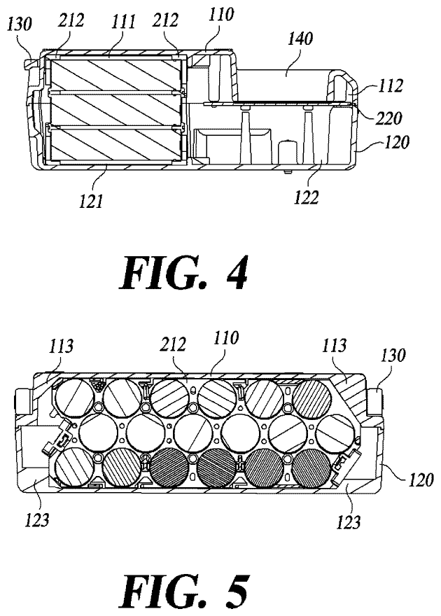

FIG. 4 is a cross-sectional view of the battery module assembly according to one embodiment of the present disclosure taken in an electrode arrangement direction of a battery cell.

FIG. 5 is a cross-sectional view of the battery module assembly according to one embodiment of the present disclosure in a direction perpendicular to the electrode arrangement direction of the battery cell.

Referring to FIGS. 1 to 5, the battery module assembly 100 according to one embodiment of the present disclosure may include a battery pack 210, a printed circuit board (PCB) 220, a lower case 120, an upper case 110, a lower support portion 123, and an upper support portion 113.

The battery pack 210 may include a plurality of battery cells 211, a plurality of harnesses 214, a battery holder 212, and a battery bus 213.

Each of the plurality of battery cells 211 may be a cylindrical battery cell. Although not shown in the drawings, the cylindrical battery cell is a type of secondary battery in which an electrode assembly is embedded in a metal can. The cylindrical battery cell may be configured by inserting an electrolyte and an electrode assembly into an open end of a cylindrical metal can and then coupling a cap to the open end. Both ends of the cylindrical battery cell may function as a cathode and an anode, respectively. However, the cylindrical battery cell may be configured differently from the above description. For example, the cylindrical battery cell may be configured as a solid-state battery cell. The plurality of battery cells 211 may be arranged in parallel with each other. Each of the plurality of battery cells 211 may be arranged such that the same electrode faces the same direction. For example, one side (e.g., a first side) of the battery pack 210 in which the plurality of battery cells 211 are arranged may be all anodes, and the other side (e.g., a second side) may be all cathodes.

The plurality of harnesses 214 may include a harness for sensing and a harness for high current.

The harness for sensing may include at least one cable and at least one sensor. The harness for sensing may measure various information related to the battery pack 210. The harness for sensing may electrically connect the battery pack 210 and the PCB 220, which is further described below, between the battery pack 210 and the PCB 220. The harness for sensing may transmit the measured information from the battery pack 210 to the PCB 220. The harness for sensing may include a voltage sensor, a temperature sensor, a humidity sensor, a safety switch, and the like.

The harness for high current may collect current generated from the plurality of battery cells 211. The harness for high current may electrically connect the battery pack 210 and the PCB 220, which is further described below, between the battery pack 210 and the PCB 220. The harness for high current may transmit the collected current from the battery pack 210 to the PCB 220. The harness for high current may include an output connector, a protection device, and the like.

The battery holder 212 may be disposed on one side (e.g., a first side) and the other side (e.g., a second side) of the plurality of battery cells 211. In this case, one side of the plurality of battery cells 211 means an anode direction of the plurality of battery cells, and the other side means a cathode direction of the plurality of battery cells. The battery holder 212 may fix the disposition of the plurality of battery cells 211. The battery holder 212 may include a number of holes equal to the number of the plurality of battery cells 211. To fix the plurality of battery cells 211, the battery holder 212 may include at least one retaining pin (not illustrated). When the plurality of battery cells 211 are coupled to the battery holder 212, the at least one retaining pin may be inserted between the plurality of battery cells 211. Alternatively, the at least one retaining pin may be disposed on an outer contour of the plurality of battery cells 211. The battery holder 212 may have a plurality of protrusions formed along an outer contour of the battery holder 212. The plurality of protrusions may be fixed to the lower case 120 and the upper case 110, which is further described below. As can be seen in FIGS. 4 and 5, at least some of the plurality of protrusions may be configured to come into close contact with at least one lower support portion 123, which is further described below, and at least one upper support portion 113, which is further described below.

The battery bus 213 may be provided on one side (e.g., a first side) and the other side (e.g., a second side) of the plurality of battery cells 211. In this case, one side and the other side of the plurality of battery cells 211 are as described above. The battery bus 213 may electrically connect the plurality of battery cells 211 inside the battery pack 210. The battery bus 213 may be made of metal or copper. The battery bus 213 may serve to maintain stability of each battery cell by minimizing a voltage difference between the plurality of battery cells 211.

The PCB 220 may serve to control the voltage, current, temperature, and the like of the battery pack 210. The PCB 220 may include a plurality of components on upper and lower surfaces. The PCB 220 may be electrically connected to the battery pack 210. The PCB 220 may transmit and receive information about the charging and discharging of the plurality of battery cells 211 to and from a battery management system (BMS). The PCB 220 may be disposed such that a normal vector of the upper surface of the PCB 220 is perpendicular to an electrode arrangement direction of the plurality of battery cells 211. For example, as shown in FIG. 2, the PCB 220 may be disposed on a lateral side of the battery pack 210. In this case, the lateral side of the battery pack 210 refers to a side in a direction in which the cathodes or anodes of the plurality of battery cells 211 are located.

The lower case 120 may include a first inner space 121 in which at least a portion of the battery pack 210 is accommodated. The lower case 120 may also include a second inner space 122 in which at least a portion of the PCB 220 is accommodated. As can be seen in FIG. 2, the first inner space 121 and the second inner space 122 can be partitioned by the shape of the lower case 120. However, unlike the above, the first inner space 121 and the second inner space 122 may be separated by installing a partition wall in the lower case 120. The lower case 120 may be combined with the upper case 110, which is further described below.

A conventional battery module is configured in a state in which a PCB and a battery pack are in contact. In such a battery module, when the battery is charged or discharged, there is a problem in that an electrical short circuit of the PCB circuit may occur due to heat generation of the battery. In order to solve this problem, the present disclosure separately forms an inner space of the battery module as the first inner space 121 and the second inner space 122. By separating the first inner space 121 and the second inner space 122 from each other, the battery pack 210 and the PCB 220 may not directly contact each other. Since the battery pack 210 and the PCB 220 are separated, a risk of an electrical short circuit occurring in the PCB 220 due to heat generation of the battery pack 210 can be reduced. In other words, by configuring the battery pack 210 and the PCB 220 not to thermally interfere with each other, the probability of an electrical short circuit of the PCB 220 and the BMS can be reduced.

The upper case 110 may include a handle 130 rotatably coupled to an upper portion of the upper case 110, a first inner space 111 in which at least a portion of the battery pack 210 is accommodated, and a second inner space 112 in which at least a portion of the PCB 220 is accommodated. As the upper case 110 is coupled to the lower case 120, the first inner spaces 111 and 121 and the second inner spaces 112 and 122 may become closed spaces. The upper case 110 may include a heat sink 140 configured to open at least a portion of the second inner space 112.

The heat sink 140 may be disposed on an outer surface of the upper case 110. The heat sink 140 may be configured to dissipate heat generated from the PCB 220. As can be seen in FIGS. 1 and 2, the heat sink 140 may be disposed in a vertical direction of the upper surface of the PCB 220 after the battery module assembly 100 of the present disclosure is assembled. The heat sink 140 may be configured in the form of a plurality of fins. Unlike the above description, the heat sink 140 may be included in the lower case 120 and disposed on an outer surface of the lower case 120. The heat sink 140 that is included in the lower case 120 may have the same configuration and effect as the heat sink 140 described above, and a detailed description thereof is omitted.

As described above, when the heat sink 140 is included in the cases 110 and 120 of the battery module, heat dissipation of the PCB 220 can be smoothly performed. When the heat dissipation of the PCB 220 is performed smoothly, the risk of an electrical short circuit occurring in the PCB 220 can be reduced.

The at least one lower support portion 123 may be formed to protrude from the inner surface of the lower case 120. The lower support portion 123 may have various shapes. For example, the lower support portion 123 may be shaped like a long bar, a column, or a sloped protrusion. The at least one lower support portion 123 may be shaped to be in close contact with the outer contour of the battery pack 210. When the battery pack 210 is accommodated in the lower case 120, the at least one lower support portion 123 may assist in fixing the battery pack 210 to the lower case 120. The at least one lower support portion 123 may be integrated with the lower case 120.

The at least one upper support portion 113 may be configured in a form in which at least a part thereof protrudes from the inner surface of the upper case 110. The upper support portion 113 may have various shapes like the lower support portion 123. When the battery pack 210 is accommodated in the upper case 110, the upper support portion 113 may assist in fixing the battery pack 210 to the upper case 110. The upper support portion 113 may be integrated with the upper case 110.

The battery module may require a smaller volume and a lower weight compared to conventional battery modules. In the case of constructing a battery module using cylindrical battery cells, it is difficult to maintain the arrangement structure of the battery cells due to the outer shape feature of the cylindrical battery cells. In order to solve this problem, the battery module may include an anchoring device in the case. The anchoring device is configured to fix the battery pack inside the battery module. The anchoring device protects the battery cells inside the battery module from external impact and maintains the arrangement structure of the battery cells. However, when the anchoring device is included in the battery module, the volume and weight of the battery module may be increased. The anchoring device makes the assembly process of the battery module complicated and increases the manufacturing cost of the battery module.

In order to solve the above problems of the conventional battery module, the battery module assembly 100 of the present disclosure includes the upper support portion 113 and the lower support portion 123 integrated with the upper case 110 and the lower case 120, respectively. In order for the battery pack 210 to be fixed in close contact with the upper support portion 113 and the lower support portion 123, the battery pack 210 may include the battery holder 212.

As can be seen in FIGS. 4 and 5, the battery holder 212 of the battery pack 210 can be fixed while being in contact with the upper support portion 113 and the lower support portion 123. As the battery pack 210 comes into close contact with the upper support portion 113 and the lower support portion 123, an impact transmitted to the battery pack 210 from the outside can be absorbed. The upper support portion 113 and the lower support portion 123 are respectively integrated with the upper case 110 and the lower case 120, so that the upper or lower support portion 113 or 123 and the upper or lower case 110 or 120 can be produced using a single mold.

When the battery pack 210 is fixed inside the battery module only by the inner shape of the case without any anchoring device, a plurality of battery cells 211 can be mounted in a stable structure through a simple assembly process. In this case, the manufacturing cost of the battery module can be reduced.

Embodiments of the present disclosure have been described for illustrative purposes. Additionally, those having ordinary skill in the art should appreciate that various modifications, additions, and substitutions are possible, without departing from the idea and scope of the claimed disclosure. Therefore, embodiments of the present disclosure have been described for the sake of brevity and clarity. The scope of the technical idea of the present embodiments is not limited by the illustrations. Accordingly, one of ordinary skill in the art would understand that the scope of the claimed disclosure is not to be limited by the above explicitly described embodiments but by the claims and equivalents thereof.

What is claimed is:

1. A battery module assembly comprising:
a battery pack including a plurality of battery cells;
a lower case including an inner space accommodating at least a portion of the battery pack;
an upper case including an inner space accommodating the remaining portion of the battery pack that is not accommodated in the lower case, the upper case being coupled to the lower case; and
at least one lower support portion configured to protrude from an inner surface of the lower case and assist in fixing the battery pack to the lower case.

2. The battery module assembly of claim 1, further comprising:
at least one upper support portion configured to protrude from an inner surface of the upper case and assist in fixing the battery pack to the upper case.

3. The battery module assembly of claim 2, wherein the at least one lower support portion is formed into a single unit with the lower case.

4. The battery module assembly of claim 2, wherein the at least one upper support portion is formed into a single unit with the upper case.

5. The battery module assembly of claim 2, wherein the battery pack comprises a battery holder disposed on a first side and a second side of the plurality of battery cells to fix an arrangement state of the plurality of battery cells.

6. The battery module assembly of claim 5, wherein at least a portion of the battery holder is in close contact with the at least one lower support portion and the at least one upper support portion so that the battery pack is fixed to the inner space of the lower case.

7. A battery module assembly comprising:
a battery pack including a plurality of battery cells;
a printed circuit board (PCB) electrically connected to the battery pack;
a lower case including a first inner space accommodating at least a portion of the battery pack and a second inner space accommodating at least a portion of the PCB; and
an upper case coupled to the lower case so that the first inner space and the second inner space become closed spaces,
wherein the first inner space and the second inner space are separately formed so that the battery pack and the PCB do not come into direct contact.

8. The battery module assembly of claim 7, wherein the first inner space and the second inner space are arranged horizontally to be separated from each other.

9. The battery module assembly of claim 7, wherein a normal vector of an upper surface of the PCB is perpendicular to an electrode arrangement direction of the plurality of battery cells.

10. The battery module assembly of claim 7, wherein the upper case includes a heat sink disposed on an outer surface of the upper case and configured to open at least a portion of the second inner space and dissipate heat generated from the PCB.

11. The battery module assembly of claim 10, wherein the heat sink is disposed in a vertical direction of an upper surface of the PCB.

12. The battery module assembly of claim 10, wherein the heat sink includes a plurality of fins.

13. The battery module assembly of claim 7, wherein the lower case comprises a heat sink disposed on an outer surface of the lower case and configured to open at least a portion of the second inner space and dissipate heat generated from the PCB.

14. The battery module assembly of claim 13, wherein the heat sink is disposed in a vertical direction of an upper surface of the PCB.

15. The battery module assembly of claim 13, wherein the heat sink includes a plurality of fins.
